(19) United States
(12) Patent Application Publication
(10) Pub. No.: US 2016/0118521 A1
(43) Pub. Date: Apr. 28, 2016

(54) MATING SYSTEM FOR PHOTOVOLTAIC ARRAY

(71) Applicant: DOW GLOBAL TECHNOLOGIES LLC, Midland, MI (US)

(72) Inventors: James R. Keenihan, Midland, MI (US); Leonardo C. Lopez, Midland, MI (US)

(21) Appl. No.: 14/898,589

(22) PCT Filed: Jun. 9, 2014
(86) PCT No.: PCT/US2014/041473

§ 371 Date: Dec. 15, 2015

Related U.S. Application Data
(60) Provisional application No. 61/856,125, filed on Jul. 19, 2013.

(51) Int. Cl. H01L 31/05

(52) U.S. Cl. CPC H01L 31/05

(57) ABSTRACT

A photovoltaic component comprising; two or more mating components spatially separated along a surface of the photovoltaic component wherein at feast one of the two or more mating components mates with a portion of one or more adjacent photovoltaic components to form a connection between one or more mating components of the one or more adjacent photovoltaic components so that a mating connection is formed between the photovoltaic component and the adjacent photovoltaic component, and wherein the at least one of the two or more mating components of the photovoltaic component and the at least one of the one or more mating components of the adjacent photovoltaic component align the photovoltaic component and the adjacent photovoltaic component relative to one another; and wherein at least one of the two or more mating components of the photovoltaic component are shaped and form a handle for carrying and/or moving the photovoltaic component.

### STATEMENT OF GOVERNMENT RIGHTS

This invention was made at least in part with U.S. Government support under contact number DE-EE0004434 awarded by the Department of Energy. The U.S. Government has certain rights in this invention.

### FIELD

The present teachings generally relate to an improved mating system for transporting and connecting two or more photovoltaic components together so that the photovoltaic components are aligned for electrically connecting the photovoltaic components together.

### BACKGROUND

Typically, photovoltaic arrays are placed in an outdoor location so that the photovoltaic arrays are exposed to sunlight. During assembly of the photovoltaic arrays the photovoltaic components are each individually moved to a support location and assembled. Generally, the photovoltaic components are placed in a support structure that houses each of the photovoltaic components so that the photovoltaic components form a photovoltaic array. Further, individual photovoltaic components making up the photovoltaic array may be directly connected to a support structure such as a roof of a house or a building. The components of the photovoltaic array are subjected to varying conditions such as wind, rain, snow, ice, heat, and direct sunlight. The changes in temperature, humidity, and precipitation may cause the components of the photovoltaic array and/or support structure to expand, contract, move, or a combination thereof in addition to a mass being applied to the photovoltaic components, a mass being applied to the support structure, or both such that each of the photovoltaic components may move relative to each other. This movement may cause a connector between two adjacent photovoltaic components to become disconnected from one or both of the photovoltaic components, be broken, a terminal to be broken, or a combination thereof so that less than all of the photovoltaic modules in the photovoltaic array are connected and produce power. Furthermore, if a connector, a photovoltaic component, or both fails and ceases to work and needs to be replaced the connectors may increase the length of time and/or difficulty required to change the connector, the photovoltaic component, or both.

Examples of some known connectors may be found in U.S. Pat. Nos. 7,442,077; 7,963,773; and 8,414,308; U.S. Patent Application Publication No. 2006/0225781; 2010/00258157; 20110220180; and 2011/0183540; European Patent No. EP2256872; and International Patent Application Nos. WO2012/044762 and WO2012/083337 all of which are incorporated by reference herein for all purposes.

It would be attractive to have two or more mating features on each photovoltaic component that align the photovoltaic components relative to each other. It would be attractive to have one or more mating features that connect two photovoltaic components and can be used to carry the photovoltaic components. What is needed is a mating feature that can be used to move the photovoltaic components and when a photovoltaic array is formed the mating features form a connection that is resistant to fluid penetration and/or resists movement of the adjoining photovoltaic components relative to each other so that an electrical connection between the photovoltaic components is maintained.

### SUMMARY

The present teachings meet one or more of the present needs by providing: a photovoltaic component comprising: two or more mating components spatially separated along a surface of the photovoltaic component, wherein at least one of the two or more mating components mates with a portion of one or more adjacent photovoltaic components to form a connection between one or more mating components of the one or more adjacent photovoltaic components so that a mating connection is formed between the photovoltaic component and the adjacent photovoltaic component, and wherein the at least one of the two or more mating components of the photovoltaic component and the at least one of the one or more mating components of the adjacent photovoltaic component align the photovoltaic component and the adjacent photovoltaic component relative to one another; and wherein at least one of the two or more mating components of the photovoltaic component are shaped and form a handle for carrying and/or moving the photovoltaic component.

One possible embodiment of the present teachings include: a photovoltaic component comprising: (a) an edge length dimension that is about 75 cm or more; (b) a secondary edge length dimension that is substantially perpendicular to the edge length dimension, the secondary edge length dimension being about 40 cm or more; and (c) one or more mating components along one or both edge regions of the edge length dimension, the secondary edge length dimension, or both; wherein the one or more mating components are a handle for carrying the photovoltaic component and for forming a connection with one or more adjacent photovoltaic components.

Another possible embodiment of the present teachings include: a method comprising: locating a photovoltaic component having two or more mating components on a support structure; aligning one or more mating components of an adjacent photovoltaic component with at least one of the two or more mating components of the photovoltaic component; forming a connection between the one or more mating components of the adjacent photovoltaic component and the at least one of the two or more mating components; and folding the adjacent photovoltaic component, the one or more mating components, or both so that the adjacent photovoltaic component covers the one or more mating components, or vice versa.

As photovoltaic components grow in size it is increasingly difficult to move and manipulate the photovoltaic components to form a photovoltaic array. Further, as the size of each photovoltaic component increases the tolerances between each photovoltaic component, expansion of each photovoltaic component, or both may need to be considered so that interconnections between two or more photovoltaic components are maintained. The present teachings provide two or more mating features on each photovoltaic component that align the photovoltaic components relative to each other. The present teachings provide one or more mating features that connect two photovoltaic components and can be used to carry the photovoltaic components. The present teachings provide a mating feature that can be used to move the photovoltaic components and when a photovoltaic array is formed the mating features form a connection that is resistant to fluid penetration and/or resists movement of the adjoining photovoltaic components relative to each other so that an electrical connection between the photovoltaic components is maintained.

### BRIEF DESCRIPTION OF THE DRAWINGS

FIG. 1A illustrates a top view of one pair of photovoltaic components including mating features of the teachings herein;

FIG. 1B illustrates a cross-sectional view of FIG. 1A;

FIG. 2A illustrates a top view of another pair of photovoltaic components including mating features of the teachings herein;

FIG. 2B illustrates a cross-sectional view of FIG. 2A;

FIG. 3A illustrates a top view of one pair of photovoltaic components including mating features of the teachings herein;

FIG. 3B illustrates a cross-sectional view of FIG. 3A;

FIG. 4A illustrates a top view of another pair of photovoltaic components including mating features of the teachings herein;

FIG. 4B illustrates a cross-sectional view of FIG. 4A;

FIGS. 5 and 6A-6B illustrate a top views of examples of the photovoltaic components including mating features of the teachings herein;

FIG. 7 illustrates a perspective view of mating features having electrical connectors of the teachings herein;

FIG. 8 illustrates a perspective view of mating features having locking connections of the teachings herein;

FIG. 9A-9B illustrates examples of two examples of two examples of photovoltaic components that include mating features in a central region; and

FIGS. 10A-10C illustrate assembly of the photovoltaic components of FIGS. 9A-9B into a partial photovoltaic array.

### DETAILED DESCRIPTION

The explanations and illustrations presented herein are intended to acquaint others skilled in the art with the teachings, its principles, and its practical application. Those skilled in the art may adapt and apply the teachings in its numerous forms, as may be best suited to the requirements of a particular use. Accordingly, the specific embodiments of the present teachings as set forth are not intended as being exhaustive or limiting of the teachings. The scope of the teachings should, therefore, be determined not with reference to the above description, but should instead be determined with reference to the appended claims, along with the full scope of equivalents to which such claims are entitled. The disclosures of all articles and references, including patent applications and publications, are incorporated by reference for all purposes. Other combinations are also possible as will be gleaned from the following claims, which are also hereby incorporated by reference into this written description. The present teachings claim priority to U.S. Patent Application Publication No. 61/856,125, filed on Jul. 19, 2013 the teachings of which are incorporated by reference herein in their entirety for all purposes.

A plurality of photovoltaic modules and/or photovoltaic components (i.e., solar components) of the teachings herein are combined together to form a photovoltaic array (also sometimes referred to as a solar array). The photovoltaic array collects sunlight and converts the sunlight to electricity. Generally, each of the photovoltaic modules may be individually placed in a structure that houses all of the photovoltaic modules forming all or a portion of a photovoltaic array. The photovoltaic modules of the teachings herein may be used with a housing that contains all of the individual photovoltaic modules that make up a photovoltaic array. Preferably, the photovoltaic array taught herein is free of a separate structure that houses all of the photovoltaic modules that make up a photovoltaic array. More preferably, each individual photovoltaic module may be connected directly to a structure and each of the individual photovoltaic modules is electrically connected together so that a photovoltaic array is formed (i.e., a building integrated photovoltaic (BIPV)). Each of the photovoltaic components, and preferably each row of photovoltaic components in the photovoltaic array may be adjacent to each other in a first direction. For example, if a photovoltaic array includes three rows of photovoltaic components and each row includes 5 photovoltaic components each of the rows and photovoltaic components within the rows may extend along a first direction. The first direction may be aligned with the slope of a roof. Preferably, the first direction is a transverse direction (i.e., perpendicular to the slope of the roof). A portion of each of the photovoltaic modules may overlap a portion of an adjacent photovoltaic module, an adjacent photovoltaic component, or both forming a shingle configuration and/or a double overlap configuration on a support structure so that the photovoltaic modules may be used as roofing shingles. Preferably, at least a portion of one photovoltaic component is in contact with an adjacent photovoltaic component so that a contiguous surface is formed, the photovoltaic components are interconnected, or both.

The photovoltaic components of the photovoltaic array may be any photovoltaic component that collects sunlight to generate electricity, any component that transfers power throughout the photovoltaic array, a photovoltaic module, any component that assists in generating energy from sunlight, an integrated flashing piece, an inverter connection, an inverter, a connector, or a combination thereof. Preferably, the photovoltaic components are a photovoltaic module, an integrated flashing piece, or both. More preferably, at least one of two photovoltaic components is a photovoltaic module. The photovoltaic components may be connected together by a connector component that is discrete from each photovoltaic component, integrally connected to one photovoltaic component and separate from another photovoltaic component, partially integrally connected to each photovoltaic component, or a combination thereof. Preferably, the photovoltaic components include one or more connectors so that two or more adjacent and/or juxtaposed photovoltaic components may be electrically connected together. For example, the two adjacent photovoltaic components may be located in close proximity to each other (i.e., a spacer, gap, shim, or the like may be located between the two adjacent photovoltaic components) so that a connector may span between and electrically connect the two adjacent photovoltaic components. The photovoltaic components, adjacent photovoltaic components, or both may be the same components, different components, or combinations of photovoltaic components of the teachings herein located next to each other, side by side, juxtaposed, in a partially overlapping relationship, or a combination thereof. As discussed herein an adjacent photovoltaic component may be any component taught herein that assists in creating a photovoltaic array so that power is generated from sunlight. A majority of the photovoltaic components and/or adjacent photovoltaic components in the photovoltaic array may be photovoltaic modules such that 50 percent or more, 60 percent or more 60 percent or more, or even 70 percent or more of the photovoltaic components are photovoltaic modules. As discussed herein a photovoltaic component and an adjacent photovoltaic component may be the same type of component just located side by side.

The photovoltaic components may have a primary edge length dimension. The primary edge length dimension may be any dimension of the photovoltaic component so that the photovoltaic component may be used to produce electricity. Preferably, the primary edge length dimension of the photovoltaic component is a length. The length is the dimension that runs from photovoltaic component to photovoltaic component along a row (i.e., perpendicular to the slope of a roof and/or transverse to the support structure). The primary edge length dimension may be about 50 cm or more, preferably about 75 cm or more, more preferably about 85 cm or more, or even about 100 cm or more. The primary edge length dimension may be about 3 m or less, about 2 m or less, or about 1.5 m or less. The photovoltaic component includes a secondary edge length dimension. The secondary edge length dimension may be any dimension of the photovoltaic component so that the photovoltaic component may be used to produce electricity. Preferably, the secondary edge length dimension is a width. The width is a dimension that is substantially perpendicular to the primary edge length dimension. For example, the width runs in the direction of the slope of a roof (i.e., longitudinal direction of the roof). The secondary edge length dimension may be about 30 cm or more, preferably about 45 cm or more, about 60 cm or more, or even about 75 cm or more. The secondary edge length dimension may be about 2 m or less, about 1.5 m or less, or about 1 m or less. The dimensions of the photovoltaic component define an area of a top and bottom of the photovoltaic component.

Each of the photovoltaic components include a top and a bottom. The top is the side of the photovoltaic component that faces the sun and the bottom is the side of the photovoltaic component that faces the support structure (e.g., roof decking of a home or building). Generally the top and the bottom are substantially parallel. Each of the photovoltaic components include one or more edge regions. Typically, each photovoltaic component is generally rectangular and includes four edge regions. However, depending on the size and shape of the photovoltaic component, the photovoltaic component may include two or more, three or more, five or more, or even six or more edge regions. The edge region may be any part of the photovoltaic component where the photovoltaic component terminates. The edge region may be a part of the photovoltaic component where an active portion, an inactive portion, or both end. The edge region may be generally parallel to one or more adjacent edge regions, generally perpendicular to one or more adjacent edge regions, may include a portion that protrudes out from the remainder of the edge region, may be a portion of a photovoltaic component that contacts an adjacent photovoltaic component, or a combination thereof. Preferably, an edge region is located directly across from an opposing edge region. The edge region may be a frame that extends around a periphery of a photovoltaic component. The edge region may have a width of about 10 cm or less, about 8 cm or less, or about 5 cm or less. The edge region may have a width of about 1 cm or more, about 2 cm or more, or about 3 cm or more. The dimensions of the edge region may vary along the length of the edge region. For example, a mating feature may extend from an edge region and the mating feature may widen the edge region at that location. The edge region may be measured from a termination point inward to a beginning of an active area, to a central region, or both.

The central region may be any region that is substantially surrounded and/or surrounded by the edge region. The central region may be a central part of the photovoltaic component. The central region may be free of a terminal edge. The central region may substantially encompass a majority (e.g. 60 percent or more, 70 percent or more, or even 80 percent or more by area) of the surface area of a side (i.e., top and/or bottom) of the photovoltaic component. The central region may include all or a portion of the inactive portion, the active portion, or both. For example, the central region may be the photovoltaic component minus the edge region.

Some and/or all of the photovoltaic components may include an inactive portion, an active portion, or both. Preferably, if the photovoltaic component is a photovoltaic module, the photovoltaic module includes both an active portion and an inactive portion. The active portion may be any portion that when contacted by sunlight produces electricity. The active portion may overlap all or a portion, an edge region, a portion of the edge region and the central region, an inactive portion, or a combination thereof of an adjacent photovoltaic component. Preferably, the active portion overlaps an inactive portion of an adjacent photovoltaic component. However, one or more mating features may extend from and/or be located within the active portion, the inactive portion, or both and be covered by and/or cover all or a portion of an adjacent photovoltaic module.

The mating feature may be any device that assists in: aligning two or more photovoltaic components, physically connecting two or more photovoltaic components, locating two or more photovoltaic components, electrically connecting two or more photovoltaic components, or a combination thereof. The mating feature may be any device that extends from a portion of a photovoltaic component, is integrally formed into a portion of a photovoltaic component, or both so that a photovoltaic component and one or more adjacent photovoltaic components may be aligned, interfitted, connected, or a combination thereof. The mating features may be configured so that the mating features may only be connected in one way such that the photovoltaic components can only be installed in one way and a mating connection formed. The mating features may aid in positioning the photovoltaic components such that an electrical connection is made between electrical components that are not part of the mating features. The mating features may position the photovoltaic components and the electrical components of at a specific position relative to a neighboring photovoltaic component so that an electrical connection is formed without using wires or other non-positioning interconnecting components. The mating features may be configured so as to prevent disconnection of the electrical components or confirm that the electrical components are connected with the correct tolerances. The mating feature may be used to carry and/or transport the photovoltaic components from one location to another location. The mating feature may be static, rigid, flexible, foldable, an integral piece, a removable piece, or a combination thereof. Each of the mating features may be substantially identical and form a connection (e.g., a mating connection and/or an electrical connection) between two photovoltaic components. There may be two or more different types of mating features so that different types of connections may be formed between two or more photovoltaic components. The mating features may be complementary components. For example, the mating features may be configured so that when connected a nesting connection is formed. The mating features may be a male component, a female component, a projection, a through-hole, or a combination thereof.

The male component may be any mating feature that extends from the photovoltaic component. Preferably, the male component is a mating feature that extends from an edge region of a photovoltaic component. However, a male component may extend from a central region of a photovoltaic component. One or more male components may extend from an edge region so that the one or more male components overlap a portion of an adjacent photovoltaic component. For example, a photovoltaic component may have one male component on one or more edges, two male components on one or more edges, two male components on one edge and two complementary components on an opposing edge, one or more male components in a central region, or a combination thereof. The male components may include a through-hole, may be a projection that extends from a side of the photovoltaic component, may include a gripping portion, may include a projection, or a combination thereof. The male portion may extend vertically from a side of the photovoltaic component, may extend laterally from the photovoltaic component (i.e., in a direction parallel to the top, the bottom, or both), or both. The male component may be configured so that male component is complementary, has a nesting relationship, an interlocking relationship, or a combination thereof to a female component.

The female component may be any component that forms a fixed connection with one or more opposing mating features. Preferably, the female component forms a connection (i.e., mating connection, electrical connection, or both) with a male component. The female component may be a recess, a through-hole, an absence of material, a cutout, an integrally formed concave portion, or a combination thereof in the photovoltaic component. The female component may receive all or a portion of a male component. The female component may receive a portion of a male component and may have a portion that is received by the male component. The female component may be located in an edge region, in the central region, or both. The female component may include the same features as the male component, an opposing feature to the male component, may be located in an opposing relationship with the male components, have a mirror image configuration as the male components, or a combination thereof. For example, a photovoltaic component may have one female component on one or more edges, two female components on one or more edges, two female components on one edge and two complementary components on an opposing edge, one or more female components in a central region, or a combination thereof. In another example, if the male component includes a projection the female portion may include a through-hole to receive the projection or if the male component includes a locking projection then the female component includes a through-hole latch, or vice versa.

The through-hole may be any part of a mating feature. The through-hole may extend through the photovoltaic component from the top to the bottom so that a projection, a hand, a carrying device, or a combination thereof may extend through and/or partially through the through-hole. The through-hole may form a handle to transport the photovoltaic component. The through-hole may be any size and shape so that the through-hole may be used as a handle to carry the photovoltaic component, may be used to form a connection with an adjacent photovoltaic component, or a combination of both. The through-hole may be round, oval, square, rectangular, symmetrical, asymmetrical, include finger grips, or a combination thereof. The through-hole may be sized and shaped to form a complementary fit for a projection. The through-hole may include one or more locking features, one or more latching features, or both so that a locked connection is formed with the through-hole. In one preferred embodiment, the through-hole may include a through-hole latch.

The through-hole latch may be any device that locks a portion of a complementary component such as a locking projection into the through-hole. The through-hole latch may lock a complementary component into the through-hole so that a tool is required to disconnect the complementary component from the through-hole latch. The through-hole latch may extend partially and/or fully around a complementary component so that the complementary component is seated within the through-hole latch. The through-hole latch may be a recessed portion that extends around all or a portion of a complementary component. The through-hole latch may be part of the female component and preferably may be part of the male component. The through-hole latch may form a locked connection with a projection and preferably a locking projection.

The projection may be any device that extends vertically from a side of the photovoltaic component, substantially perpendicular to a surface of a photovoltaic component, extends from a surface of a male component, extends from a surface of a female component, or a combination thereof. The projection may be any size and shape so that the projection forms a complementary fit with a through-hole in an adjacent component. The projection may be a partial bubble so that one side the projection includes a hollowing portion forming a handle, and so that the other side of the projection fills a through-hole to prevent fluid penetration. The projection may be round, oval, square, rectangular, symmetrical, asymmetrical, include finger grips, or a combination thereof. The projection may be generally cylindrically shaped, mushroom shaped, cone shaped, ‘T’ shaped, or a combination thereof. The projection may have a sufficient height so that the projection forms a connection with an adjacent component. The projection may have a sufficient height so that the projection extends all of the way through a through-hole, into a recess, the photovoltaic components cannot be disconnected by lateral movement (i.e., a photovoltaic component may need to be lifted to disconnect the photovoltaic modules), or a combination thereof. The height of the projection may be a distance from a top of the projection to a base of the projection where it is attached to the photovoltaic component. The projection may have a largest height of about 2 mm or more, about 4 mm or more, about 5 mm or more. The projection may have a largest height of about 5 cm or less, about 3 cm or less, or about 1 cm or less. The projection may have a sufficient area so that the when the projection is in contact with a complementary component of an adjacent photovoltaic component a fixed connection is formed, an interlocking connection is formed, the projection snaps into the complementary component, or a combination thereof. The area of the projection may be slightly larger than the area of the complementary component so that once the projection extends into the complementary component a tight connection is formed such that the photovoltaic components cannot move relative to each other. For example, the complementary component may be a through-hole in an adjacent photovoltaic module and the projection may be pressed into the through-hole so that the inner dimensions of the through-hole are pressed against the outer dimensions of the projection forming a friction fit. Preferably, the area of the projection is larger than the complementary component so that a locked connection is formed.

The locking projection may be any part of the projection that forms a locked connection with a complementary component. The locking projection may form a connection that requires a tool to disconnect. The locking projection once in a locked state may form a permanent connection. Preferably, the locking projection may form a connection that is releasable. Preferably, the locking projection may be mushroom shaped, ‘T’ shaped, or both. The locking projection may be malleable and then solidified when a connection is formed. The locking projection may be rigid and the complementary component such as a through-hole may be malleable so that the locking projection may extend through the complementary component. The locking projection may be expandable, contractible, may change shapes, or a combination thereof. For example, the locking projection may have a first shape to extend through a through-hole and once through the through-hole the locking projection may be expanded to a second shape to form a locked connection. The complementary component to the locking projection may be a through-hole, a recess, or both.

The recess may be any part of the photovoltaic component where material is removed, an absence of material, a hole does not extend through the photovoltaic component, a cavity, or a combination thereof. The recess may receive all or a portion of the male component, a projection, a locking component, or a combination thereof. Preferably, the recess is shaped so that the shape of the recess is complementary to the shape of the male component. The recess may be formed in a top, a bottom, an edge region, a central region, an active portion, an inactive portion, or a combination thereof of the photovoltaic component. The recess may be configured so that once a mating feature and/or complementary component extends into the recess, movement of the mating feature and/or complementary component may be substantially limited and/or prevented. The recess may be completely void of other features or may be partially void of other features. For example, some recesses may include projections and/or through-holes and some recesses may be free of projections and/or through-holes. The recess may include one or more lock ports.

The lock port may be any size and shape so that the lock port assists in creating a fixed connection with a mating feature of an adjacent photovoltaic component. The lock port may be located on and/or within any mating component. Preferably the lock port is part of a female component. The lock port may be any size and shape so that a connecting mating feature cannot be removed through lateral movement, in-plane movement, movement in a direction along the photovoltaic components, or a combination thereof. Stated another way the lock port may prevent a connecting mating feature from being pulled out of a recess but will not prevent the connecting mating feature from being vertically moved to disconnect two photovoltaic components. The lock port may prevent the photovoltaic components from moving relative to each other. The lock port may form a connection with a lock on an adjacent mating feature, may grip a lock on an adjacent mating feature, may form an interconnect with an adjacent mating feature, or a combination thereof.

The lock may be any device of a mating feature that forms a connection with an adjacent mating feature so that movement of two or more photovoltaic components is restricted, two or more photovoltaic components are connected together, or both The lock may extend from a mating feature. Preferably, the lock extends from a male component so that when the male component is connected to a female component the lock resists the male component from being removed from the female component. The mating device may include one or more, two or more, three or more, four or more, or even five or more, locks. Preferably, the mating device includes at least two locks and the locks extend from opposite sides of the mating device. Preferably, the lock and the lock port form a complementary fit so that the lock port houses the lock and resists a mating component from being pulled out of the recess. In addition to forming a mating connection the lock may assist in creating an electrical connection.

The mating features may assist in forming an electrical connection, may include electrical components that form an electrical connection, or both. The mating features may include an electrical connector. The electrical connector may be any device that forms one side of an electrical connection. The electrical connector may extend from a mating feature so that the electrical connector extends into a connection port and forms an electrical connection. The electrical connector may plug into a connection port. The electrical connector may extend from a male component, may extend from a female component, or both. The electrical connector may be substantially flat so that when a mating connection is formed between two mating features an electrical connection is formed. The electrical connector may be located on a top side, a bottom side, in a recess, on a mating feature, or a combination thereof so that an electrical connection is formed by the electrical connector. Preferably, the electrical connector is on a male component. The electrical connector may be configured so that the electrical connector forms an electrical connection with a connection port in and/or on an an adjacent photovoltaic component and preferably an adjacent mating feature of an adjacent photovoltaic component.

The connection port may be any device that forms an electrical connection with an electrical connector on an adjacent photovoltaic component. The connection port may be any device extends into and/or receives all or a portion of an electrical connector. The connection port may be substantially flat so that when a mating connection is formed between two mating features an electrical connection is formed. The connection port and/or electrical connector may be magnetic so that when the connection port and the electrical connector are in close proximity the magnets may assist in aligning the devices so that an electrical connection is formed. The connection port may be located in and/or on a male component, a female component, a projection, or a combination thereof. The connection port and the electrical connector may assist in forming a mating connection as well as an electrical connection.

A mating connection may be any connection where two mating features are in contact and assist in connecting two adjacent photovoltaic components. A mating connection may be a removable connection, a permanent connection, a physical connection, an electrical connection, or a combination thereof. A mating connection may be where two mating features are configured in a nesting relationship. A mating connection may be a connection where one mating feature cannot be pulled from an adjacent mating feature, where in-plane movement does not disconnect the mating features, or both. One or both of the mating features may be moved to form a mating connection.

One or both of the mating features may be movable so that the mating features may be moved into contact with one another to form a mating connection. The mating features may be movable (e.g., a foldable component). The female components may be static and the male components may be movable. Preferably, when the male components are movable the male components may be foldable so that the male components may extend behind the photovoltaic component. The foldable components may be folded and stored so that the mating features do not extend beyond an edge of the photovoltaic component during transport so that the photovoltaic component fits on a standard pallet and when the photovoltaic component arrives at a desired location the foldable components may be unfolded so that the foldable component may be used as a handle for carrying. The foldable component may be folded back after a mating connection is formed so that the mating feature is concealed from view in an installed state. The foldable component may fold one or both directions. Preferably, the foldable component only folds to be concealed from view. The foldable component may be folded back into a pocket and/or recess during transportation so that the foldable component is not damaged, the photovoltaic component conforms to standard dimensions, or both. The pocket and/or recess may be any size and shape so that the foldable component may be flush with the remainder of the side of the photovoltaic component and protected when not being used as a handle and/or to form a mating connection. The foldable component may be folded during a method of installing photovoltaic components to form a photovoltaic array.

A method may include one or more of the following step and the order of the steps may performed in virtually any order. The method may include a step of unfolding, removing from a pocket, removing from a recess, or a combination thereof the foldable component. The method may include a step of carrying a photovoltaic component by the mating feature. The method may include a step of locating the photovoltaic components on a support structure, locating the photovoltaic components relative to each other, or both. The photovoltaic components may be connected to the support structure. The photovoltaic components may be aligned relative to one another. One or more mating features may be extended from one photovoltaic component to an adjacent photovoltaic component. One or more mating features may be pressed into an adjacent photovoltaic component. A mating connection may be formed between two or more photovoltaic components. A photovoltaic component may be flipped upside down so that a top of one photovoltaic component and a top of an adjacent photovoltaic component are face to face. A foldable component may be connected to one or more adjacent mating features. The photovoltaic component may be rotated about the foldable component so that a back of the photovoltaic component faces the top of the adjacent photovoltaic component. An active portion of one photovoltaic component may be located on an inactive portion of one or more adjacent photovoltaic components. An electrical connection may be formed during, after, simultaneously with, before, or a combination thereof the step of forming a mating connection. A locking projection may be moved through a through-hole latch forming a mating connection. A portion of one photovoltaic component may be overlapped over a portion of an adjacent photovoltaic component.

FIG. 1A illustrates a photovoltaic component 100 and an adjacent photovoltaic component 102 that are photovoltaic components 2. Both the photovoltaic component 100 and the adjacent photovoltaic component 102 include an active portion 4 and an inactive portion 6. The inactive portions 6 include a mating feature 18 in each edge region 60. One edge region 60 includes a mating feature 18 that is a female component 22 and an opposite edge region 60 includes a mating feature 18 that is a male component 20 so that the male component 20 of the photovoltaic component 100 extends over the female component 22 of the adjacent photovoltaic component 102 aligning the photovoltaic components relative to each other. The male components 20 as illustrated include a through-hole 28 so that the male components 20 can be used as a handle to move the photovoltaic components. FIG. 1B illustrates a cross-sectional view of the photovoltaic component 100 and the adjacent photovoltaic component 102 along lines A-A of FIG. 1A. As illustrated, the through-hole 28 of the male components 20 is shown.

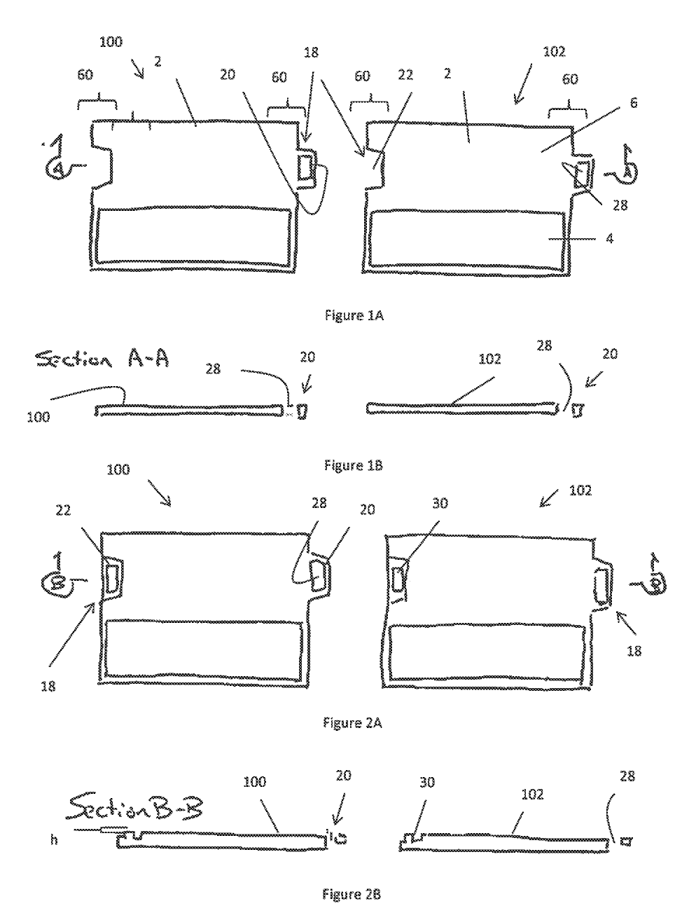

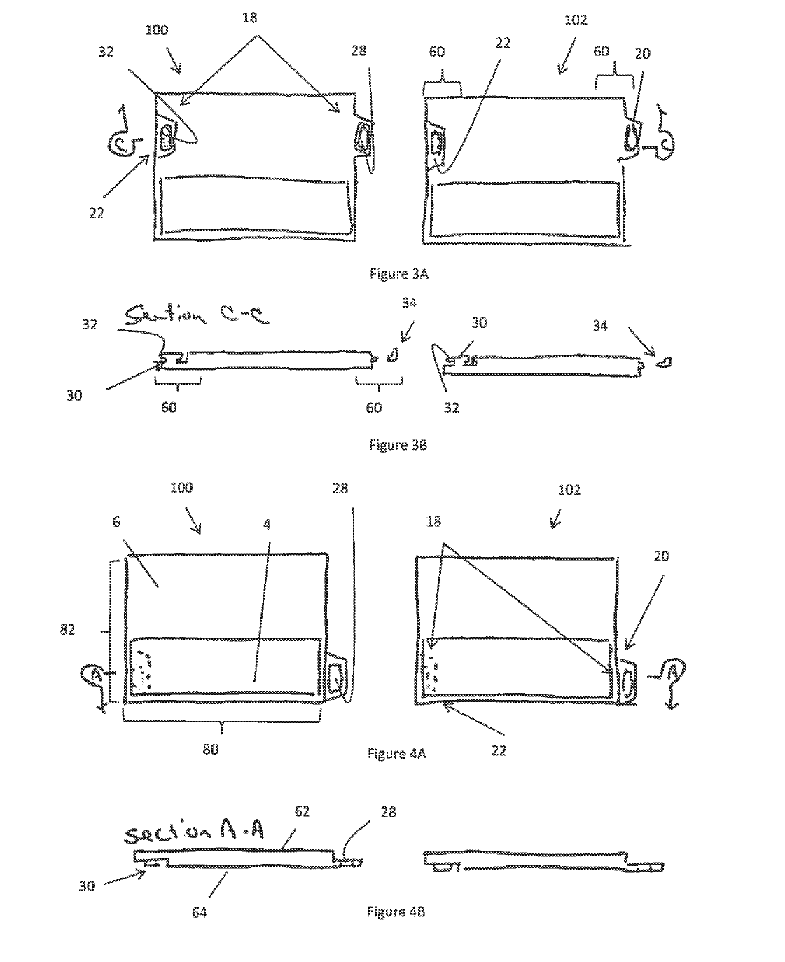

FIG. 2A illustrates a photovoltaic component 100 and an adjacent photovoltaic component 102 each having a mating feature 18 in each edge region. The mating feature 18 on one edge is a female component 22 having a projection 30 and a male component 20 on the other edge having a through-hole 28. FIG. 2B illustrates a cross-sectional view along lines B-B of FIG. 2A. As illustrated the photovoltaic component 100 and the adjacent photovoltaic component 102 include a male component 20 having a through-hole 28 that receives the projection 30 of the female component 22 so that a mating connection is formed between the photovoltaic component 100 and the adjacent photovoltaic component 102. As illustrated, the projection has a height (h) extending from a surface of the photovoltaic component 100 to a top of the projection 30

FIG. 3A illustrates a top view of a photovoltaic component 100 and an adjacent photovoltaic component 102 each having a mating feature 18 in each edge region 60 and FIG. 3B illustrated a cross-sectional view of FIG. 3A. The mating feature 18 on one edge is a female component 22 having a projection 30 having a locking projection 32 and the mating feature 18 on the opposing edge is a male component 20 having a through-hole 28. The male component 20 includes a through-hole latch 34 that forms a fixed connection under the locking projection 32.

FIG. 4A illustrates a top view of a photovoltaic component 100 and an adjacent photovoltaic component 102 and FIG. 4B illustrates a cross-sectional view of FIG. 4A. The photovoltaic component 100 and the adjacent photovoltaic component 102 each include an active portion 4 and an inactive portion 6. The photovoltaic component 100 includes a primary edge length direction 80 and a secondary edge length direction 82. As illustrated, the active portion 6 includes a mating feature 18 on each edge so that one edge has a male component 20 having a through-hole 28 and the other edge has a female component 22. The photovoltaic component 100 and the adjacent photovoltaic component 102 each include a top surface 62 and a bottom surface 64. The female portion 22 extends from the top surface 62 and the male portion 20 extends from the bottom surface 64 so that the male portion 20 extends over the female portion 22 and a projection 30 of the female portion extends into the through-hole 28 in the male portion 20.

FIG. 5 illustrates a photovoltaic component 100 and an adjacent photovoltaic component 102. The photovoltaic component 100 includes mating features 18 in opposing edge regions and both of the mating features 18 are male components 20 having through-holes 28. The adjacent photovoltaic component 102 includes mating features 18 in opposing edge regions and both of the mating features 18 are female components 22 that received the male components 20 of the photovoltaic component 100 so that the photovoltaic component 100 and the adjacent photovoltaic component 102 are aligned relative to one another. A connection port 42 is located on the photovoltaic component 100 below the male component 20 and an electrical connector 40 is located on the adjacent photovoltaic component 102 below the female component 22 so that when the male component 20 and the female component 22 are aligned to form a mating connection the electrical connector 40 and connection port 42 are aligned to form an electrical connection.

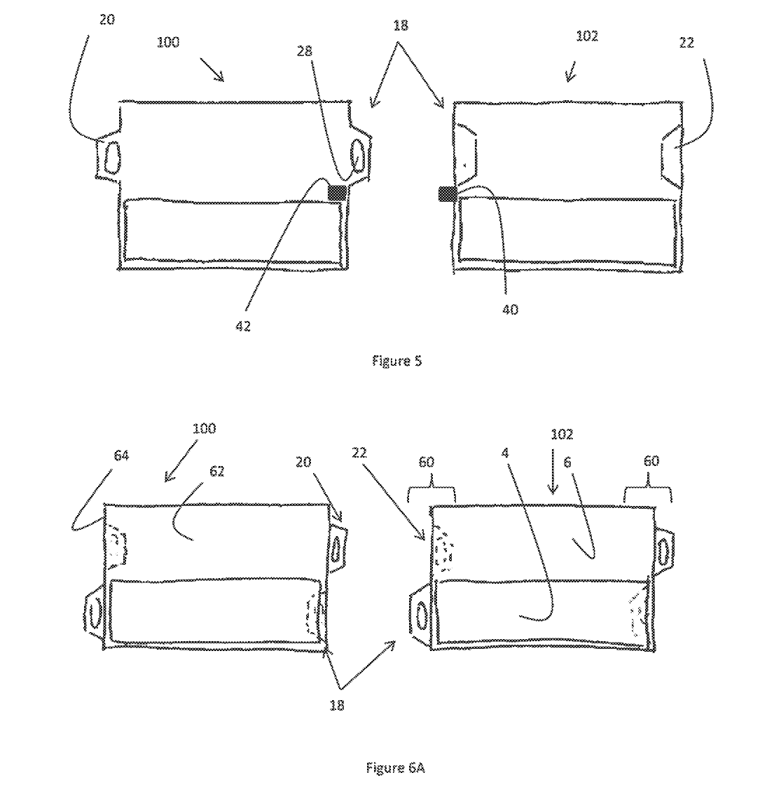

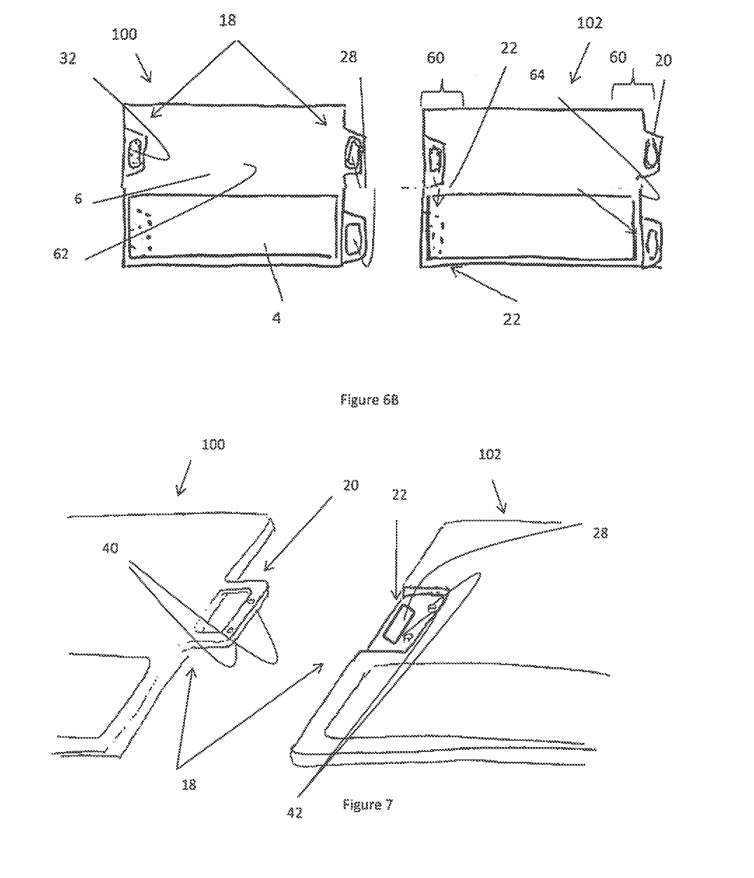

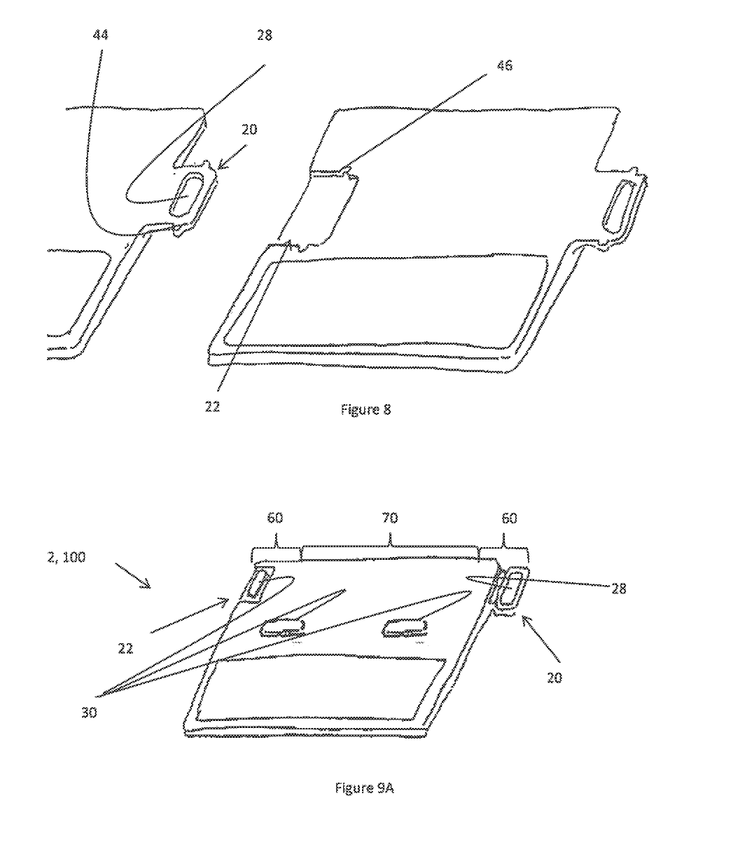

FIGS. 6A and 6B illustrates a photovoltaic component 100 and an adjacent photovoltaic component 102. Both the photovoltaic component 100 and the adjacent photovoltaic component 102 include a top 62 side and a bottom 64 side. As illustrated in FIG. 6A, each edge region 60 includes mating features 18 that are both male components 20 and both female components 22. The top 62 side includes a male component 20 extending therefrom and the bottom 64 side includes a female component 22 in an alternating relationship so that the male component 20 overlaps the female component 22 and connects the photovoltaic component 100 to the adjacent photovoltaic component 102. Both include an active portion 4 and an inactive portion 6, and each active portion 4 and each inactive portion 6 include both a male component 20 and a female component 22.

As illustrated in FIG. 66, one edge region 60 includes mating features 18 that are both male components 20 and an opposing edge region 60 includes mating features 18 that are both female components 22. Both top 62 side and the bottom side 64 include a male component 20 extending therefrom and a female component 22 extending therefrom in an alternating relationship so that the male component 20 overlaps the female component 22 and connects the photovoltaic component 100 to the adjacent photovoltaic component 102. Both include an active portion 4 and an inactive portion 6, and each active portion 4 and each inactive portion 6 include both a male component 20 and a female component 22.

FIG. 7 illustrates a photovoltaic component 100 and an adjacent photovoltaic component 102 including mating features 18 that assist in both electrically connecting and physically connected the photovoltaic component 100 and the adjacent photovoltaic component 102 together. As illustrated, both mating features 18 include a through-hole 28 so that both mating features 18 can be used as a handle. The photovoltaic component 100 includes a male component 20 including electrical connectors 40 and the adjacent photovoltaic component 102 includes a female component 22 including connection ports 42 so that when the electrical connectors 40 contact the connection ports 42 an electrical connection is formed.

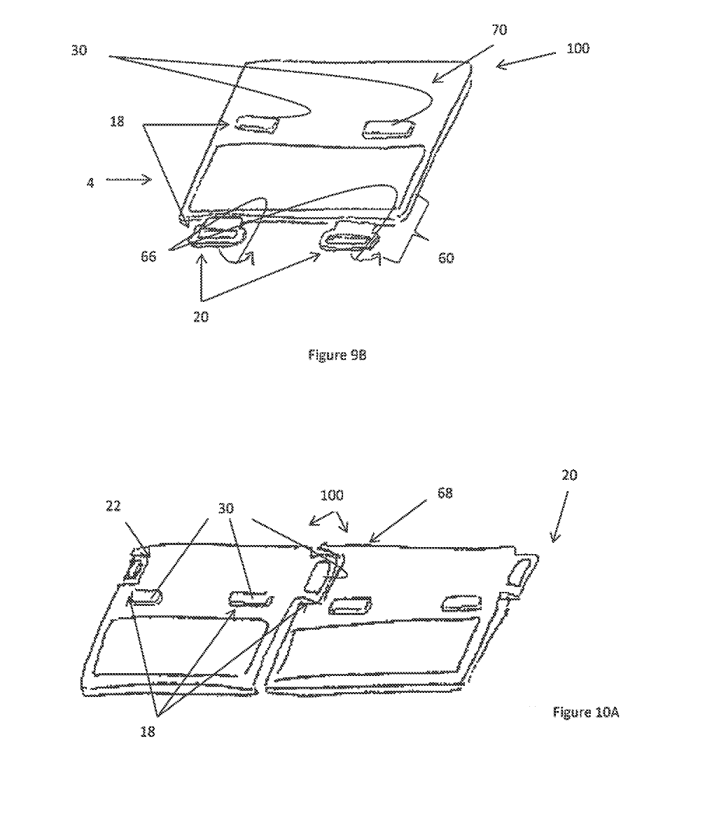

FIG. 8 illustrates the male component 20 including a through-hole 28 so that the male component 20 can be used as a handle. The male component 20 includes a lock 44 that fits into a lock port 46 of the female component 22 so that a secured connection is formed between two photovoltaic components.

FIG. 9A illustrates one embodiment of a photovoltaic component 100. The photovoltaic module 2 includes a male component 20 in one edge region 60 and a female component 22 in an opposing edge region 60. The male component 20 includes a through-hole 28 for receiving a projection 30. As illustrated, projections 30 extend from the female component 22 and a central region 70 of the photovoltaic component 100 includes a pair of projections 30.

FIG. 9B illustrates an example of a photovoltaic component 100 that includes four mating features 18. A pair of projections 30 are located within a central region 70 of the photovoltaic component 100. A pair of male components 20 extend from an edge region 60 of the active portion 4. The male components 20 are foldable in a direction of folding 66 so that the male components 20 can be moved under the photovoltaic component 100.

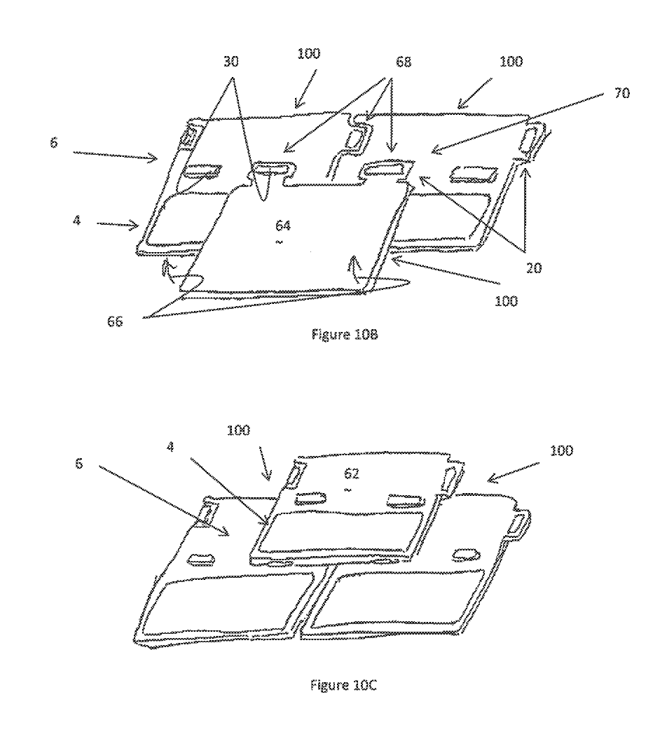

FIGS. 10A-10C illustrate sequence of using the mating features 18 to connect the photovoltaic components 100 of FIGS. 9A and 9B together to form a photovoltaic array. FIG. 10A illustrates two photovoltaic components 100 of FIG. 9A connected together so that a male component 20 and a female component 22 connect forming a mating connection 68 as the male component 20 extends over and into communication with a projection 30.

FIG. 10B illustrates a photovoltaic component 100 of FIG. 9B being connected to the photovoltaic components 100 of FIG. 10A. The male components 20 are connected to projections 30 in a central region 70 of the inactive portion 6 so that the bottom 64 faces away from the active portion 4 of the photovoltaic components 100. The photovoltaic component 100 of FIG. 9B once a mating connection 68 is formed the photovoltaic component 100 is folded in the direction of folding 66.

FIG. 100 illustrates the photovoltaic component 100 of FIG. 9B folded so that the top 62 faces up and the active portion 4 of FIG. 9B rests on the inactive portion 6 of the photovoltaic components 100 of FIG. 10A.

Any numerical values recited herein include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

Unless otherwise stated, all ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints.

The disclosures of all articles and references, including patent applications and publications, are incorporated by reference for all purposes. The term “consisting essentially of” to describe a combination shall include the elements, ingredients, components or steps identified, and such other elements ingredients, components or steps that do not materially affect the basic and novel characteristics of the combination. The use of the terms “comprising” or “including” to describe combinations of elements, ingredients, components or steps herein also contemplates embodiments that consist essentially of the elements, ingredients, components or steps. By use of the term “may” herein, it is intended that any described attributes that “may” be included are optional.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps.

It is understood that the above description is intended to be illustrative and not restrictive. Many embodiments as well as many applications besides the examples provided will be apparent to those of skill in the art upon reading the above description. The scope of the teachings should, therefore, be determined not with reference to the above description, but should instead be determined with reference to the appended claims, along with the full scope of equivalents to which such claims are entitled. The disclosures of all articles and references, including patent applications and publications, are incorporated by reference for all purposes. The omission in the following claims of any aspect of subject matter that is disclosed herein is not a disclaimer of such subject matter, nor should it be regarded that the inventors did not consider such subject matter to be part of the disclosed inventive subject matter.

1) A photovoltaic component comprising:
two or more mating components spatially separated along a surface of the photovoltaic component,
wherein at least one of the two or more mating components mates with a portion of one or more adjacent photovoltaic components to form a connection between one or more mating components of the one or more adjacent photovoltaic components so that a mating connection is formed between the photovoltaic component and the adjacent photovoltaic component, and
wherein the at least one of the two or more mating components of the photovoltaic component and the at least one of the one or more mating components of the adjacent photovoltaic component align the photovoltaic component and the adjacent photovoltaic component relative to one another; and
wherein at least one of the two or more mating components of the photovoltaic component are shaped and form a handle for carrying and/or moving the photovoltaic component.

2) The photovoltaic component of claim 1, wherein the photovoltaic component includes an active portion and an inactive portion and the two or more mating components are connected to the inactive portion, are formed in the inactive portion, are within a region formed by the inactive portion, are located outside of the active portion, or a combination thereof.

3) The photovoltaic component of claim 1, wherein the photovoltaic component includes an active portion and an inactive portion and at least one of the two or more mating components is located within the active portion, one of the two or more mating components is located within the inactive portion, the two or more mating components are both located in the active portion, or a combination thereof.

4) The photovoltaic component of claim 1, wherein the two or more mating components of the photovoltaic component and the one or more mating components of the adjacent photovoltaic components are configured so that one of the two mating components of the photovoltaic component can only form the mating connection in one configuration with one of the one or more mating components of the adjacent photovoltaic component.

5) The photovoltaic component of claim 1, wherein the two or more mating components are located in opposite edge regions of the photovoltaic component.

6) The photovoltaic component of claim 1, wherein the photovoltaic component includes one or more male components in both a first edge region and a second edge region or one or more female components in both the first edge region and the second edge region.

7) The photovoltaic component of claim 6, wherein the photovoltaic component includes the one or more male components and the one or more female components in both a first edge region and a second edge region.

8) The photovoltaic component of claim 6, wherein the photovoltaic component includes the one or more male components in a first edge region and the one or more female components in a second edge region.

9) The photovoltaic component of claim 6, wherein the female components are a recess that has a shape that is substantially identical in shape to the male components.

10) The photovoltaic component of claim 1, wherein the male components, the female components, or both include a through-hole.

11) The photovoltaic component of claim 1, wherein the female component includes a through-hole and the male component includes a projection so that the projection extends into and covers the though hole of the female component, and the projection forms a portion of a handle, the projection is a handle, or both.

12) The photovoltaic component of claim 1, wherein the two or more mating components of the photovoltaic component includes an electrical connection so that when one of the two mating components is connected to one of the one or more mating components of the adjacent photovoltaic component both an electrical connection and a physical connection are formed.

13) The photovoltaic component of claim 1, wherein the two or more mating components extend beyond an edge of the photovoltaic component so that a connection is formed with the one or more mating components of the adjacent photovoltaic component and the two or more mating components are foldable so that once the connection is formed the two or more mating components are concealed under the photovoltaic component.

14) A photovoltaic component comprising:
a. an edge length dimension that is about 75 cm or more;
b. a secondary edge length dimension that is substantially perpendicular to the edge length dimension, the secondary edge length dimension being about 40 cm or more;
c. a top side,
d. a bottom side, and
e. one or more mating components located on the top side, the bottom side, or bot and being located along one or both edge regions of the edge length dimension, the secondary edge length dimension, or both;
wherein the one or more mating components are a handle for carrying the photovoltaic component and for forming a connection with one or more adjacent photovoltaic components.

15) A method comprising:
locating a photovoltaic component having two or more mating components on a support structure;
aligning one or more mating components of an adjacent photovoltaic component with at least one of the two or more mating components of the photovoltaic component;
forming a connection between the one or more mating components of the adjacent photovoltaic component and the at least one of the two or more mating components;
optionally folding the adjacent photovoltaic component, the one or more mating components, or both so that the adjacent photovoltaic component covers the one or more mating components, or vice versa; and
connecting the photovoltaic component to the support structure; and
wherein at least one of the two or more mating components of photovoltaic component are shaped and form a handle for carrying and/or moving the photovoltaic component.
